(19) United States
(12) Patent Application Publication
(10) Pub. No.: US 2025/0045482 A1
(43) Pub. Date: Feb. 6, 2025

(54) METHODS AND SYSTEMS FOR ASSET MANAGEMENT

(71) Applicant: NATIONAL UNIVERSITY OF SINGAPORE, Singapore (SG)

(72) Inventors: Sushant Suhas GARUD, Singapore (SG); Iftekhar Abubakar KARIMI, Singapore (SG)

(73) Assignee: NATIONAL UNIVERSITY OF SINGAPORE, Singapore (SG)

(21) Appl. No.: 18/709,378

(22) PCT Filed: Nov. 11, 2022
(86) PCT No.: PCT/SG2022/050826

§ 371 Date: May 10, 2024

(30) Foreign Application Priority Data
Nov. 12, 2021 (SG) 10202112608S

(51) Int. Cl. G06F 30/20; G06F 11/34

(52) U.S. Cl. CPC G06F 30/20; G06F 11/3457

(57) ABSTRACT

Disclosed is a method for managing digital twins of a plurality of physical assets. The system comprises a digital platform, database and a plurality of processors. The processors import real world data from the physical assets to the database, process the real world data to generate calibration data, map a plurality of digital twins to the digital platform, each digital twin for simulating a corresponding physical asset, predict simulation data by the digital twins, compare the simulation data with the calibration data to assess performance of the digital twins, determine a set of low-performance digital twins based on the performance of the digital twins, and apply an optimization model to update the digital twins.

### TECHNICAL FIELD

The present invention relates, in general terms, to systems and methods for asset management. In particular, the present invention relates to the generation and updating of digital twins of physical assets.

### BACKGROUND

The digital ecosystems of chemical and process industries are expanding with the rapid pace of digitalization. Several models are being developed using various digital twin technologies (first-principal models, machine learning models, simulation models, etc.) and native development software.

Chemical and process industries have been early proponents of modelling and simulation. Artificial Intelligence (AI) and Machine Learning (ML) technologies spearheading the current wave of Industry 4.0 rely on myriad models, also known as digital twins, being developed across different tools/software with varied complexities and performances. The COVID-19 pandemic has accelerated the digital transformation efforts and investments across industries, especially in Chemical and Process Industries due to their resource-intensive nature. Many Industry 4.0 technologies employ soft sensors and/or digital twins under the hood, which in turn depend on the (simulation) models.

These models (digital assets) are typically developed by the domain experts using various software but utilized by plant personnel with diverse backgrounds and levels of training. Understanding and utilizing such models is not straightforward and demands significant time and attention from the user. Due to this, these models exist in silos and are shelved when not in use, rendering them stale or dormant (i.e., out of tuning) for dynamic operations.

However, it is a time and resource consuming task to tune such dormant models before re-deploying them for plant data analysis. A very real concern in the minds of industry operators is how to make sure that their huge investment in sophisticated digitalisation technologies does not go waste due to changes that their process and/or operations may experience.

It would be desirable to overcome or ameliorate at least one of the above-described problems, or at least to provide a useful alternative.

### SUMMARY

Disclosed is a system for managing digital twins of a plurality of physical assets, the system comprising:
a digital platform;
a database; and
a plurality of processors for:
   importing real world data from the physical assets to the database; processing the real world data to generate calibration data;
   mapping a plurality of digital twins to the digital platform, each digital twin for simulating a corresponding physical asset;
   predicting simulation data by the digital twins;
   comparing the simulation data with the calibration data to assess performance of the digital twins;
   determining a set of low-performance digital twins based on the performance of the digital twins; and
   applying an optimization model to update the set of low-performance digital twins.

Importing the real world data from the physical assets to the database may comprise generating hierarchical representation of the physical assets.

The calibration data may comprise data from one or more sensors for each physical asset, and applying an optimization model to update the digital twins may comprise modifying one or more parameters of each digital twin in the set until predicted simulation data corresponds to the calibration data.

Importing the real world data from the physical assets to the database may comprise identifying missing data streams for each physical asset.

Processing the real world data to generate the calibration data may comprise:
identifying one or more outliers in the real world data;
removing the outliers from the real world data to generate the calibration data; and
storing the calibration data in the database.

Identifying the outliers in the real world data may be based on one or more unsupervised learning algorithms. Removing the outliers from the real world data may comprise using information associated with the physical assets to remove the outliers.

Mapping the digital twins to the digital platform may comprise establishing a bi-directional interface between the digital platform and a corresponding digital twin.

Mapping the digital twins to the digital platform may comprise structuring the digital platform based on the number and type of the digital twins.

Applying the optimization model to update the set of low-performance digital twins may comprise:
generating a set of objective values based on the set of low-performance digital twins and the calibration data;
employing a machine learning model, based on the objective values, to replace the set of low-performance digital twins with an optimized set of digital twins; and
mapping the optimized set of digital twins to the digital platform.

The system may comprise a classifier for identifying information associated with the digital twins.

Also disclosed is a method for managing digital twins of a plurality of physical assets, the system comprising:
importing real world data from the physical assets to a database;
processing the real world data to generate calibration data;
mapping a plurality of digital twins to a digital platform, each digital twin for simulating a corresponding physical asset;
predicting simulation data by the digital twins;
comparing the simulation data with the calibration data to assess performance of the digital twins;
determining a set of low-performance digital twins based on the performance of the digital twins; and
applying an optimization model to update the set of low-performance digital twins.

Importing the real world data from the physical assets to the database may comprise generating hierarchical representation of the physical assets. The calibration data may comprise data from one or more sensors for each physical asset, and applying an optimization model to update the digital twins may comprise modifying one or more parameters of each digital twin in the set until predicted simulation data corresponds to the calibration data.

Importing the real world data from the physical assets to the database may comprise identifying missing data streams for each physical asset.

Processing the real world data to generate the calibration data may comprise: identifying one or more outliers in the real world data;
removing the outliers from the real world data to generate the calibration data; and
storing the calibration data in the database.

Identifying the outliers in the real world data may be based on one or more unsupervised learning algorithms.

Removing the outliers from the real world data may comprise using information associated with the physical assets to remove the outliers.

Mapping the digital twins to the digital platform may comprise establishing a bi-directional interface between the digital platform and a corresponding digital twin.

Mapping the digital twins to the digital platform may comprise structuring the digital platform based on the number and type of the digital twins.

Applying the optimization model to update the set of low-performance digital twins may comprise:
generating a set of objective values based on the set of low-performance digital twins and the calibration data;
employing a machine learning model, based on the objective values, to replace the set of low-performance digital twins with an optimized set of digital twins; and
mapping the optimized set of digital twins to the digital platform.

The method may further comprise using a classifier for identifying information associated with the digital twins.

Advantageously, embodiments use a generalized hierarchical representation of physical system information within the paradigm. A modular and centralized nature of the representation ensures ease of hosting for a variety of digital twins.

Advantageously, embodiments use Contextual knowledge-based mapping of digital twins. This equips the paradigm with necessary system knowledge to drive digital twins from different native software without supervision.

Advantageously, embodiments use a self-formulating black-box optimization framework. Enables automatic formulation of parameter optimization problem and updating solution to evolve the digital twin, in turn enhancing availability & reliability of digital twins.

Advantageously, embodiments use a Low-code/No-code framework for executing scenarios with digital twins. This enhances usability and reach of digital twins to the personnel with little or no domain expertise.

### BRIEF DESCRIPTION OF THE DRAWINGS

Embodiments of the present invention will now be described, by way of non-limiting example, with reference to the drawings in which:

FIG. 1 is a schematic describing the workflow of the paradigm;

FIG. 2 shows the receiving system information and building a hierarchy graph;

FIG. 3 is a schematic of an hierarchical system representation using directed graph;

FIG. 4 shows the importing and processing of raw data into the database;

FIG. 5 shows a method of processing the real world data to generate calibration data;

FIG. 6 shows a performance assessment for a digital twin by comparing field instruments and model predictions, two instruments showing significant deviation;

FIG. 7 shows a performance assessment for a digital twin by comparing field instruments and model predictions after recalibrating, with instruments showing improved performance;

FIG. 8 is a block diagram showing an exemplary system in which embodiments of the invention may be practiced; and

FIG. 9 shows a schematic of email notification generated by the paradigm as part of auto-reporting protocol.

### DETAILED DESCRIPTION

The present invention relates to the systems and methods for managing generation and updating of digital twins of physical assets. A new paradigm for sustaining the digital twins developed using different technologies, birthed by different native software, and deployed at different scales is presented. The proposed approach facilitates a central hosting and evolution of various digital twins through continuous assessment, identification of performance issues, and smart decision making for model calibration, training, and versioning.

The proposed systems and methods are able to consolidate a variety of digital twins within the digital ecosystem and enable standardized interfaces for hosting and driving these digital twins. Furthermore, the systems and methods reconcile field data streams to generate cleaned datasets by removing bad and/or idle state data streams. Such reconciled data sets are further processed by employing statistical transformations. The processed data sets are employed through the interfaces to continuously evaluate the hosted digital twins and monitor their performance. Performance deterioration above a threshold triggers the decision engine that automatically determines and executes the necessary actions, for example model recalibration and versioning—i.e. low-performance digital twins are detected and recalibrated or updated to a new version. The system and methods equip the decision engine to automatically formulate and solve a problem, for example parameter optimization, to update the affected digital twin. Overall, the proposed paradigm ensures sustainable digital transformation by tending to digital twins throughout their lifecycle.

Once a digital twin (of any scale and fidelity) has been developed, the present invention will keep it aware and alive without physical intervention. This leads us to a series of investigations. The first investigation is designing the mapping architecture of a digital twin so that it can easily be updated without external expert help and knowledge of its internals, which normally are totally hidden from the end-user. The second investigation is to accommodate changes in features or parameters over time. The third investigation aims at periodically updating these parameters and features without any manual intervention; monitoring the accuracy of a digital twin. The fourth investigation focuses on developing methods for using online process data to estimate and update various parameters and features. The fifth investigation is exploiting and combining the powers of AI, data analytics, and digital twin technologies to achieve the goal.

Responsive to the above investigations an adaptive AI-powered paradigm is designed that can host multiple digital assets, embed the domain experts' knowledge for each asset, automatically assess the model performance at periodic intervals against the plant data, trigger the automated tuning protocol when the model performance starts degrading, execute Machine Learning-assisted model version control, and finally generate the insights report.

The proposed paradigm comprises two configuration stages, viz. design (asset birth) and operations (asset evolution). In the design stage, newly created models are mapped to within paradigm's environment, tuned with available plant data, and stored as base versions. In the operational stage, the digital assets are live, and all models are continuously assessed against the plant data.

Such automated continuous assessment helps in identifying the models that require retuning or experience operational changes in the process/plant—e.g. models that deviate more than a predetermined proportion (e.g. 5% from the actual plant data. The proposed tuning protocol calibrates stale models by automatically determining a calibration data set, formulating optimization problem, obtaining new set of parameter values, and updating these parameter values within the model to create a new version. At the heart of the paradigm, a machine learning driven decision engine is employed that uses calibration and validation data for each model and assists in online model identification, evaluation, and versioning.

With this, the proposed paradigm comprises of following novel features. The first is digital representation of physical systems. The second is a systematic approach to digitally represent the physical systems (such as enterprises, sites, plants, assets, and instruments) within the proposed paradigm while ensuring compatibility with the existing digital ecosystem (e.g. ERP systems). The third novel feature relates to digital representation of models, that is, a systematic approach to represent the models/digital twins within the paradigm. It serves as a container for all the communication between the environment and the digital twin's native software. The fourth novel feature relates to data storage and pre-processing. The present disclosure aims to query the raw instrument data, process the sensor data to remove outliers and bad values, and store them in a unified database. The fifth feature relates to bidirectional interfaces with external software. The present invention establishes a connection between the environment and various digital twin's native software (steady-state/dynamic) for querying and updating them. The sixth feature is a ML-driven decision engine. The present invention builds machine learning based decision engine for online, assessment of instrument data, model identification, and model maintenance with each new calibration. The seventh novel feature relates to an automated assessment, tuning and versioning protocol used to determine the calibration and validation data sets and perform calibration by solving an optimisation problem. Said automated assessment, tuning and versioning protocol can also update model version log and store newly calibrated model. The eighth feature relates to operational insights. That is, the present invention generates operational insights based on model evaluation and recalibration.

Overall, the proposed paradigm integrates above mentioned features to form a unified solution for managing and maintaining the digital assets, in turn keeping them aware and alive for on-demand usage; ultimately acting as a single source of all digital assets within an enterprise.

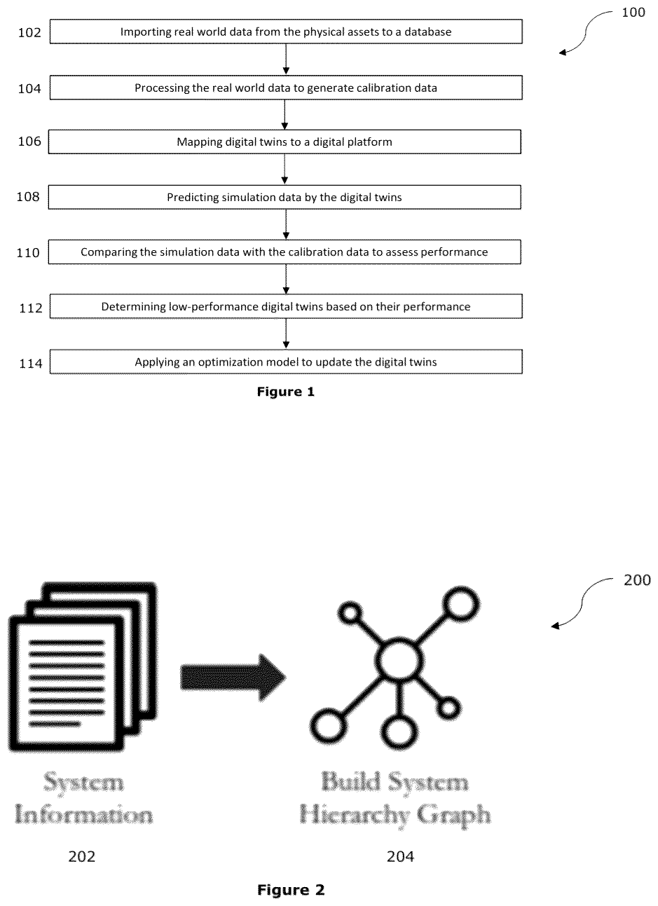

FIG. 1 illustrates an example method 100 for managing digital twins of a plurality of physical assets. The method 100 comprises:
Step 102: importing real world data from the physical assets to a database;
Step 104: processing the real world data to generate calibration data;
Step 106: mapping a plurality of digital twins to a digital platform, each digital twin for simulating a corresponding physical asset;
Step 108: predicting simulation data by the digital twins;
Step 110: comparing the simulation data with the calibration data to assess performance of the digital twins;
Step 112: determining a set of low-performance digital twins based on the performance of the digital twins; and
Step 114: applying an optimization model to update the digital twins.

At step 102, in some embodiments, importing the real world data from the physical assets to the database comprises generating hierarchical representation 204 of the physical assets (see 200). That is, step 102 involves developing hierarchical representation of physical assets (which may be represented as system information 202), which can be visualized in FIG. 2.

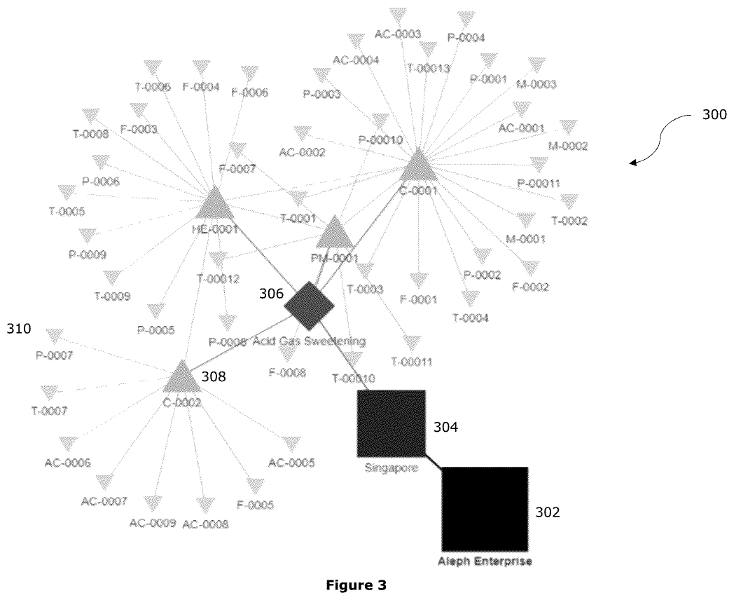

FIG. 3 illustrates an example hierarchical system representation 300 created by using directed graph. Each node in the graph represents a specific physical system (such as enterprise 302, site 304, plant 306, asset 308, and instrument 310) that is represented in the digital twin. In particular, as shown in FIG. 3, each enterprise 302 may comprise a plurality of sites 304. Each site may comprise a plurality of plants. Each plant may comprise a plurality of equipment. Each equipment may comprises several instruments. As such, different nodes are connected to each other so as to form a connected directed graph.

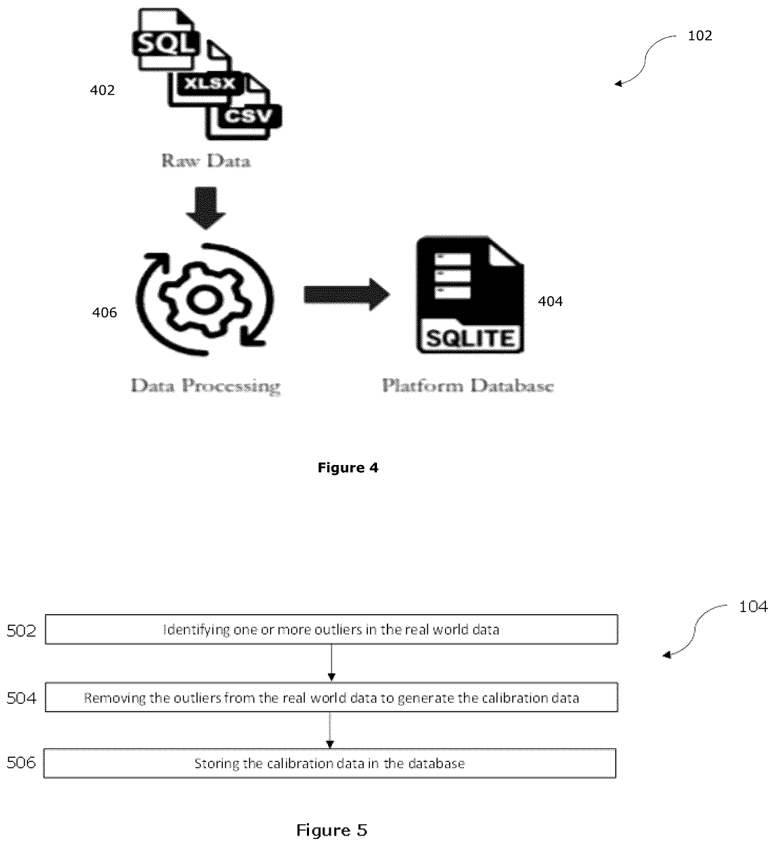

It will be appreciated that the real world data to be imported to the database may be raw data, which may be not complete and contains missing data points. In the present disclosure, as shown in FIG. 4, importing the real world raw data 402 from the physical assets to the database 404 comprises data processing (see 406), which includes identifying missing data streams for each physical asset and removing extraneous or incomplete information. In particular, the raw data 402 is first processed to assess for any missing data streams for each sensor.

The calibration data may comprise data from one or more sensors for each physical asset. In the present disclosure, automatically obtaining calibration/test data is not a simple case of separating data sets. During the initial model configuration, the historical raw data 402 is processed to identify possible operating states. Potentially, each operating state can represent a version of the model, thus the calibration and validation data from each operating state is selected. This is achieved by finding the most stable data regions using a reachability distance metric. Besides, there is a possibility of calibrating the live models. Importing the real world raw data 402 from the physical assets to the database 404 may also comprise configure time zone of the raw historical data. For this, the calibration data is selected from the time when the model starts showing deterioration in performance. Such data is collected for a specified period before starting the calibration.

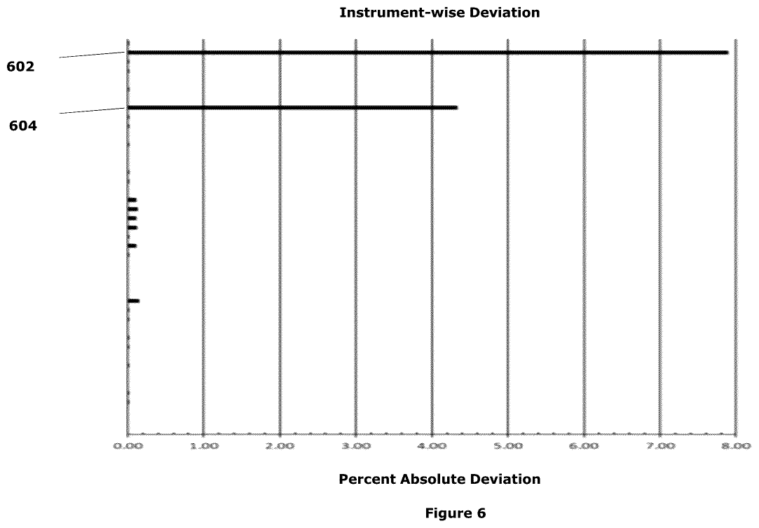

FIG. 5 shows details of step 104. In particular, processing the real world data (e.g. the raw data) to generate the calibration data comprises:
Step 502: identifying one or more outliers in the real world data;
Step 504: removing the outliers from the real world data to generate the calibration data; and
Step 506: storing the calibration data in the database.

To be clear, removing the outliers from the real world data comprising using information associated with the physical assets to remove the outliers. In one example, if the low (L) and high (H) bounds for measurements are provided explicitly for each sensor, then they are applied to remove apparent outliers.

Additionally, offline sensor information is used to drop data when the equipment/plant is not working. Besides, we employ multi-variate outlier analysis that relies on unsupervised learning models to determine any potential outliers. Said unsupervised learning refers to the use of artificial intelligence (AI) algorithms to identify patterns in data sets containing data points that are neither classified nor labelled. Once the potential outliers are identified, the raw data will be processed so as to obtain, and store cleaned sensor-wise data. The calibration data can also be selected and stored using the cleansed data.

It will be appreciated that said outlier analysis is performed by the system so as to identify changes in behaviour of a specific tool rather than the system as a whole. In the present invention, a plant comprises several equipment and instruments/sensors. Thus, any equipment level information is valid across the plant. Generally, any data that does not follow normal operation can be deemed as outlier including bad sensors, noisy sensors, offline states, etc. Rather than data resolution, presence of strategic instruments/sensors providing complementing information is important in getting realistic inferences.

At step 106, as shown in FIG. 1, mapping the digital twins to the digital platform comprises establishing a bi-directional interface between the digital platform and a corresponding digital twin. Mapping the digital twin (i.e., original model) into the environment (i.e., digital platform) can be done automatically or manually. In some embodiments, the mapping is automatic subject to the initial customization. The original model is mapped to the environment through communication containers that comprises mapping information. The containers are automatically generated by the digital platform wherein it recommends instruments/sensors that can be present in the selected model.

In the present disclosure, mapping the digital twins to the digital platform comprises structuring the digital platform based on the number and type of the digital twins. In particular, the user needs to confirm and/or add/remove sensors as necessary. Furthermore, the user may provide linking between the selected sensors and their counterparts in the model. Once confirmed by the user, the platform automatically checks for the sanity of the provided mapping and highlights issues if any. Said mapping process may include mapping soft instruments with hard/field instruments, mapping soft equipment with hard/field equipment, mapping parameter schema of all the equipment comprised in the model, as well as mapping instrument and equipment through automatic validation by checking the digital twin meta-data. It will be appreciated that this is a one-time configuration and this meta-data can be automatically transferred to subsequent versions with model evolution.

The proposed method 100 has been applied to a case study system in the field of chemical processing. As highlighted earlier, the first step involves developing hierarchical representation of physical assets, which can be visualized in FIG. 3. Next, the digital twin is mapped to the paradigm's environment and the raw data is imported for assessing the performance.

The initial performance assessment shows deviation in two instruments namely 602 and 604 (see FIG. 6). The performance is evaluated during one day period. The deviation of 602 and 604 is of 4% and 8%, respectively. With this, the decision engine comes into action to first assess possibility of bad data coming from instruments. For this, various statistical tests are performed to ensure data sanity of violating instruments. Since there are no issues with the data, the decision engine checks for similar condition in the historical data by using machine learning-based models and similarity-based metrics. After concluding that there is a need for recalibration (see step 110 and 112 of method 100), the decision engine identifies the section(s) of the digital twin to be updated by propagating the deviating instruments—i.e. moving through the hierarchy graph to identify the asset to which the deviating instruments relate to.

The present invention thus propagates deviating instruments to identify equipment needing recalibration. In this case, the decision engine narrows down to a particular equipment which is connected to both 602 and 604 for recalibration, formulates the calibration-optimization problem, solves it to obtain the new optimal parameter set, updates them within the digital twin, and creates a new version of the digital twin.

At step 114, an essential sub-step is formulating the optimisation problem. In particular, once a calibration is deemed necessary, the decision engine determines the equipment and its parameters (for example from the parameters schema) that needs to be calibrated. These parameters, which need to be converted to optimization-compatible decision variables, serve as decision variables in the optimization. The objective is to match the calibration data collected from field sensors with the data coming from the model (i.e., soft-sensors). This is a black-box optimization, which considers the design and analysis of algorithms for problems where the structure of the objective function and/or the constraints defining the set is unknown or non-existent. The black-box optimization algorithm iterates over parameter values until termination is reached i.e. optimal parameters are identified. In some embodiment, ML-based approach can be used to solve the optimization problem. It will be appreciated that applying an optimization model to update the digital twins comprises modifying one or more parameters of each digital twin in the set until predicted simulation data corresponds to the calibration data.

Another sub-step of step 114 is generating the classifier. We now discuss purpose of the classifier and how to define the different dataset classes. In the present disclosure, the method 100 comprises using a classifier for identifying information associated with the digital twins. With time, any mapped model evolves resulting in multiples versions valid for various operations and data sets. This information is captured in the classifier so that the platform can quickly determine the current model for the incoming live data. This classifier can be updated with time by adding/merging/removing model versions. The classes are based on the calibration data sets discussed earlier. The associated artefacts for the new version will then be created and stored, and said supervised-learning based classifier will be updated for determining active digital twins.

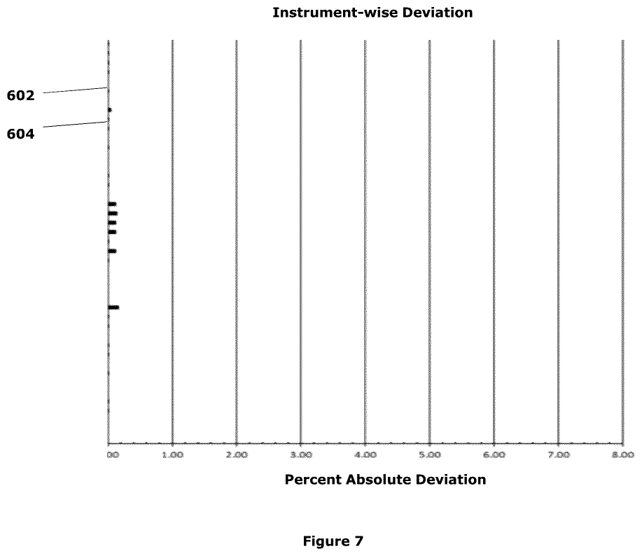

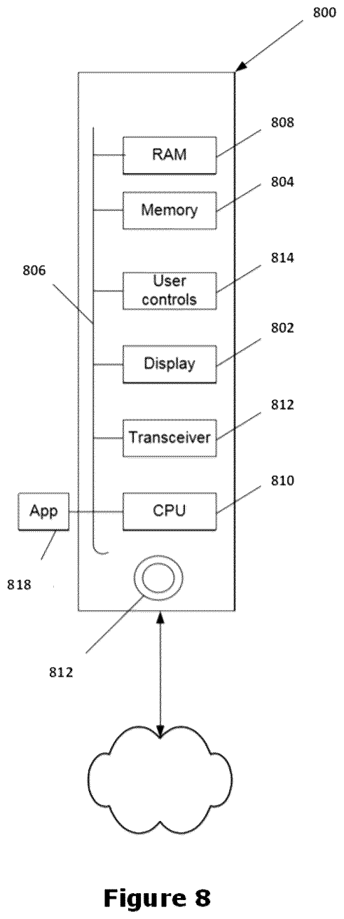

The updated digital twin shows excellent performance with respect to all the instruments (see FIG. 7), thus highlighting successful calibration. Again, the present disclosure employs the validation dataset using newly calibrated model, and compares field sensor data with soft sensor data to compute deviation. The deviations of two instruments 602 and 604 are 0.05% and 0.01%, respectively.

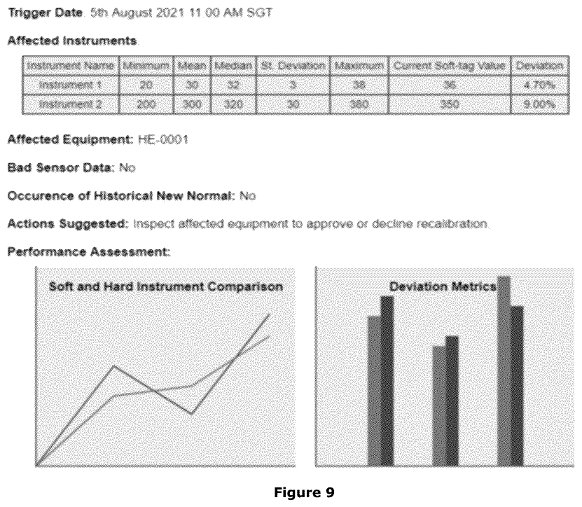

FIG. 9 shows a schematic of email notification generated by the paradigm as part of auto-reporting protocol. Besides digital twin management and maintenance, the proposed paradigm enables low-code/no-code scenario execution using the hosted digital twins. This democratizes the utilization of digital twins across different personnel with varying domain expertise.

In the prior art, the digital twin tuning is either performed manually by users for chosen data or in rare cases by using in-built scripting option within the modelling software. Although the latter can be available in some modelling software environment, it is not well developed and requires extensive programming and domain expertise. There is no single environment for hosting all digital assets from different solution providers. Therefore, the novel paradigm is well situated to complement the current digital ecosystem in process industries and push the boundaries of digitalisation state-of-the-art. In summary, the proposed paradigm ensures maximum resource utilization by hosting various models, keeping them up to date and alive for instant deployment with minimal external domain expert engagement. Additionally, it provides the report of tuning and assessment to users, providing insights into the operational changes, and their impact on the models. With this, the proposed paradigm can serve as a backbone to the ongoing digital transformation efforts by reducing resource, time, and cost required for maintaining, managing, and keeping alive the digital assets. This invention aims to enhance the overall operational efficiency of manufacturing industries and will serve a wide range of industries such as oil and gas, petrochemicals, bulk and fine chemicals, pharmaceuticals, and power plants.

The present invention also relates to a system for managing digital twins of a plurality of physical assets, the system comprising:
a digital platform;
a database; and
a plurality of processors for:
   importing real world data from the physical assets to the database;
   processing the real world data to generate calibration data;
   mapping a plurality of digital twins to the digital platform, each digital twin for simulating a corresponding physical asset;
   predicting simulation data by the digital twins;
   comparing the simulation data with the calibration data to assess performance of the digital twins;
   determining a set of low-performance digital twins based on the performance of the digital twins; and
   applying an optimization model to update the digital twins.

FIG. 8 is a block diagram showing an exemplary system (such as computer device) 800, in which embodiments of the invention may be practiced. The computer device 800 may be a mobile computer device such as a smart phone, a wearable device, a palm-top computer, and multimedia Internet enabled cellular telephones when used in training the model, and, for use in controlling a vehicle or other machine for autonomous driving, may be an on-board computing system or a mobile device such as an iPhone™ manufactured by Apple™, Inc or one manufactured by LG™, HTC™ and Samsung™, for example, or other device in communication with the vehicle or other machine and configured to send control commands thereto and to receive information on human interventions from the vehicle or other machine.

As shown, the mobile computer device 800 includes the following components in electronic communication via a bus 806:
(a) a display 802;
(b) non-volatile (non-transitory) memory 804;
(c) random access memory (“RAM”) 808;
(d) N processing components 810;
(e) a transceiver component 812 that includes N transceivers; and
(f) user controls 814.

Although the components depicted in FIG. 8 represent physical components, FIG. 8 is not intended to be a hardware diagram. Thus, many of the components depicted in FIG. 8 may be realized by common constructs or distributed among additional physical components. Moreover, it is certainly contemplated that other existing and yet-to-be developed physical components and architectures may be utilized to implement the functional components described with reference to FIG. 8.

The display 802 generally operates to provide a presentation of content to a user, and may be realized by any of a variety of displays (e.g., CRT, LCD, HDMI, micro-projector and OLED displays).

In general, the non-volatile data storage 804 (also referred to as non-volatile memory) functions to store (e.g., persistently store) data and executable code. The system architecture may be implemented in memory 804, or by instructions stored in memory 804.

In some embodiments, the non-volatile memory 804 includes bootloader code, modem software, operating system code, file system code, and code to facilitate the implementation components, well known to those of ordinary skill in the art, which are not depicted nor described for simplicity.

In many implementations, the non-volatile memory 804 is realized by flash memory (e.g., NAND or ONENAND memory), but it is certainly contemplated that other memory types may be utilized as well. Although it may be possible to execute the code from the non-volatile memory 804, the executable code in the non-volatile memory 804 is typically loaded into RAM 808 and executed by one or more of the N processing components 810.

The N processing components 810 in connection with RAM 808 generally operate to execute the instructions stored in non-volatile memory 804. As one of ordinarily skill in the art will appreciate, the N processing components 810 may include a video processor, modem processor, DSP, graphics processing unit (GPU), and other processing components.

The transceiver component 812 includes N transceiver chains, which may be used for communicating with external devices via wireless networks. Each of the N transceiver chains may represent a transceiver associated with a particular communication scheme. For example, each transceiver may correspond to protocols that are specific to local area networks, cellular networks (e.g., a CDMA network, a GPRS network, a UMTS networks), and other types of communication networks.

The system 800 of FIG. 8 may be connected to any appliance 418, such as one or more sensors for sensing parameters relating to asset performance, to receive measurements of that performance against which to test the digital twins.

It should be recognized that FIG. 8 is merely exemplary and in one or more exemplary embodiments, the functions described herein may be implemented in hardware, software, firmware, or any combination thereof. If implemented in software, the functions may be stored on or transmitted over as one or more instructions or code encoded on a non-transitory computer-readable medium 804. Non-transitory computer-readable medium 804 includes both computer storage medium and communication medium including any medium that facilitates transfer of a computer program from one place to another. A storage medium may be any available medium that can be accessed by a computer.

It will be appreciated that many further modifications and permutations of various aspects of the described embodiments are possible. Accordingly, the described aspects are intended to embrace all such alterations, modifications, and variations that fall within the spirit and scope of the appended claims or statements.

Throughout this specification and the claims or statements that follow, unless the context requires otherwise, the word “comprise”, and variations such as “comprises” and “comprising”, will be understood to imply the inclusion of a stated integer or step or group of integers or steps but not the exclusion of any other integer or step or group of integers or steps.

The reference in this specification to any prior publication (or information derived from it), or to any matter which is known, is not, and should not be taken as an acknowledgment or admission or any form of suggestion that that prior publication (or information derived from it) or known matter forms part of the common general knowledge in the field of endeavor to which this specification relates.

1. A system for managing digital twins of a plurality of physical assets, the system comprising:
a digital platform;
a database; and
a plurality of processors for:
importing real world data from the physical assets to the database, and generating a hierarchical representation of the physical assets;
processing the real world data to generate calibration data;
mapping a plurality of digital twins to the digital platform, each digital twin for simulating a corresponding physical asset, by establishing a bi-directional interface between the digital platform and each digital twin;
predicting simulation data by the digital twins;
comparing the simulation data with the calibration data to assess performance of the digital twins;
determining a set of low-performance digital twins, based on the performance of the digital twins propagated through the hierarchical representation, by moving through the hierarchical representation; and
applying an optimization model to update the set of low-performance digital twins.

2. (canceled)

3. The system of claim 1, wherein the calibration data comprises data from one or more sensors for each physical asset, and applying an optimization model to update the digital twins comprises modifying one or more parameters of each digital twin in the set until predicted simulation data corresponds to the calibration data.

4. The system of claim 1, wherein importing the real world data from the physical assets to the database comprises identifying missing data streams for each physical asset.

5. The system of claim 1, wherein processing the real world data to generate the calibration data comprises:
identifying one or more outliers in the real world data;
removing the outliers from the real world data to generate the calibration data; and
storing the calibration data in the database.

6. The system of claim 5, wherein identifying the outliers in the real world data is based on one or more unsupervised learning algorithms.

7. The system of claim 5, wherein removing the outliers from the real world data comprising using information associated with the physical assets to remove the outliers.

8. (canceled)

9. The system of claim 1, wherein mapping the digital twins to the digital platform comprises structuring the digital platform based on the number and type of the digital twins.

10. The system of claim 1, wherein applying the optimization model to update the set of low-performance digital twins comprises:
generating a set of objective values based on the set of low-performance digital twins and the calibration data;
employing a machine learning model, based on the objective values, to replace the set of low-performance digital twins with an optimized set of digital twins; and
mapping the optimized set of digital twins to the digital platform.

11. The system of claim 1, comprising a classifier for identifying information associated with the digital twins.

12. A method for managing digital twins of a plurality of physical assets, the method comprising:
importing real world data from the physical assets to a database, and generating a hierarchical representation of the physical assets;
processing the real world data to generate calibration data;
mapping a plurality of digital twins to a digital platform, each digital twin for simulating a corresponding physical asset, by establishing a bi-directional interface between the digital platform and each digital twin;
predicting simulation data by the digital twins;
comparing the simulation data with the calibration data to assess performance of the digital twins;
determining a set of low-performance digital twins, based on the performance of the digital twins propagated through the hierarchical representation, by moving through the hierarchical representation; and
applying an optimization model to update the set of low-performance digital twins.

13. The method of claim 12, wherein importing the real world data from the physical assets to the database comprises generating hierarchical representation of the physical assets.

14. The method of claim 12, wherein the calibration data comprises data from one or more sensors for each physical asset, and applying an optimization model to update the digital twins comprises modifying one or more parameters of each digital twin in the set until predicted simulation data corresponds to the calibration data.

15. The method of claim 12, wherein importing the real world data from the physical assets to the database comprises identifying missing data streams for each physical asset.

16. The method of claim 12, wherein processing the real world data to generate the calibration data comprises:
identifying one or more outliers in the real world data;
removing the outliers from the real world data to generate the calibration data; and
storing the calibration data in the database.

17. The method of claim 16, wherein identifying the outliers in the real world data is based on one or more unsupervised learning algorithms.

18. The method of claim 16, wherein removing the outliers from the real world data comprising using information associated with the physical assets to remove the outliers.

19. The method of claim 12, wherein mapping the digital twins to the digital platform comprises establishing a bi-directional interface between the digital platform and a corresponding digital twin.

20. The method of claim 12, wherein mapping the digital twins to the digital platform comprises structuring the digital platform based on the number and type of the digital twins.

21. The method of claim 12, wherein applying the optimization model to update the set of low-performance digital twins comprises:
generating a set of objective values based on the set of low-performance digital twins and the calibration data;
employing a machine learning model, based on the objective values, to replace the set of low-performance digital twins with an optimized set of digital twins; and
mapping the optimized set of digital twins to the digital platform.

22. The method of claim 12, comprising using a classifier for identifying information associated with the digital twins.
